(19) United States
(12) Patent Application Publication
(10) Pub. No.: US 2024/0162352 A1
(43) Pub. Date: May 16, 2024

(54) SEMICONDUCTOR DEVICE AND METHOD OF MANUFACTURING THE SAME

(71) Applicant: SK hynix Inc., Icheon (KR)

(72) Inventor: Seok Man HONG, Icheon (KR)

(21) Appl. No.: 18/302,692

(22) Filed: Apr. 18, 2023

(30) Foreign Application Priority Data
Nov. 10, 2022 (KR) 10-2022-0149181

(51) Int. Cl. H01L 29/86; H01L 21/443; H01L 27/02; H01L 29/66

(52) U.S. Cl. CPC H01L 29/86; H01L 21/443; H01L 27/02; H01L 29/66969; H01L 29/43

(57) ABSTRACT

A semiconductor device may include a first electrode including carbon, an anti-oxidation layer located on the first electrode, a barrier layer located on the anti-oxidation layer and including oxide, a variable resistance layer located on the barrier layer, and a second electrode located on the variable resistance layer. One or both of the anti-oxidation layer and the barrier layer may each have a thickness of 0.1 nm to 2 nm.

### CROSS-REFERENCE TO RELATED APPLICATION

This application claims priority under 35 U.S.C. § 119 to Korean Patent Application No. 10-2022-0149181 filed on Nov. 10, 2022, which is incorporated herein by reference in its entirety.

### BACKGROUND

### 1. Technical Field

Embodiments of the present disclosure relate to an electronic device and a method of manufacturing the same, and more particularly, to a semiconductor device and a method of manufacturing the same.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a first electrode including carbon; an anti-oxidation layer located on the first electrode; a barrier layer located on the anti-oxidation layer and including oxide; a variable resistance layer located on the barrier layer; and a second electrode located on the variable resistance layer.

In an embodiment, a method of manufacturing a semiconductor device may include: forming a first electrode including carbon; forming an anti-oxidation layer on the first electrode; forming a barrier layer including oxide on the anti-oxidation layer; forming a variable resistance layer on the barrier layer; and forming a second electrode on the variable resistance layer.

### BRIEF DESCRIPTION OF THE DRAWINGS

FIGS. 1A, 1B, 1C, 1D, and 1E are diagrams for describing the structure of a semiconductor device in accordance with an embodiment.

FIG. 2 is a diagram for describing a semiconductor device in accordance with an embodiment.

FIG. 3A and FIG. 3B are diagrams illustrating a semiconductor device in accordance with an embodiment.

FIG. 4 is a diagram for describing a semiconductor device in accordance with an embodiment.

FIG. 5A and FIG. 5B are diagrams for describing a method of manufacturing a semiconductor device in accordance with an embodiment.

FIG. 6 is a diagram for describing a method of manufacturing a semiconductor device in accordance with an embodiment.

FIG. 7 is a diagram for describing a method of manufacturing a semiconductor device in accordance with an embodiment.

### DETAILED DESCRIPTION

Various embodiments are directed to a semiconductor device having a stable structure and improved characteristics and a manufacturing method thereof.

According to the present technology, it is possible to provide a semiconductor device having a stable structure and improved reliability.

Hereafter, embodiments in accordance with the technical spirit of the present disclosure will be described with reference to the accompanying drawings.

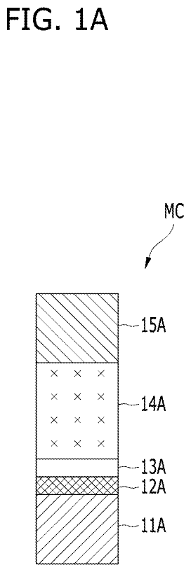

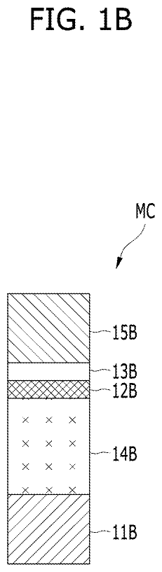

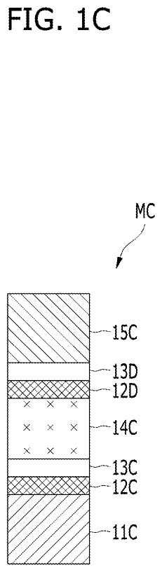

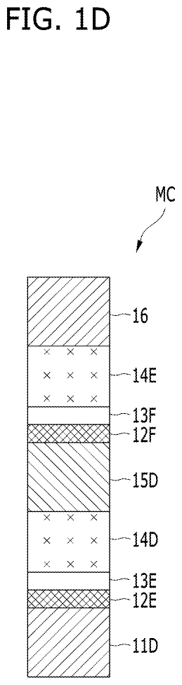

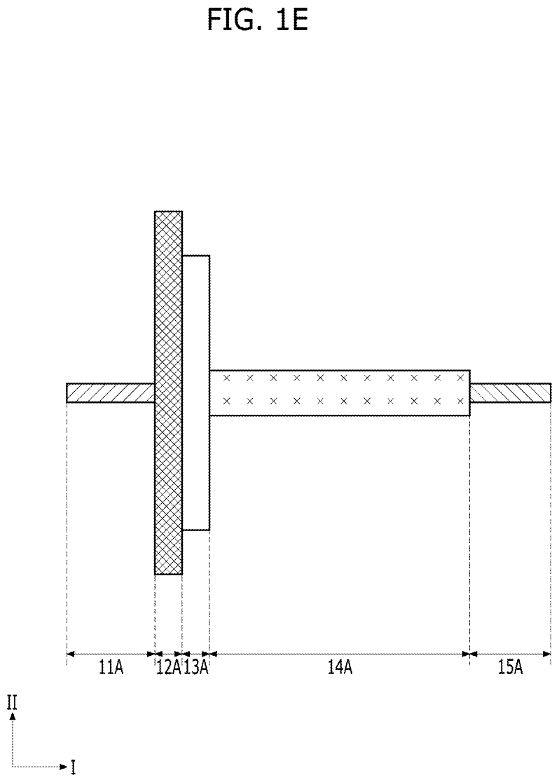

FIG. 1A to FIG. 1E are diagrams for describing the structure of a semiconductor device in accordance with an embodiment.

Referring to FIG. 1A, the semiconductor device may include a first electrode 11A, an anti-oxidation layer 12A, a barrier layer 13A, a variable resistance layer 14A, and a second electrode 15A. The semiconductor device may include a memory cell MC, and the memory cell MC may include the first electrode 11A, the anti-oxidation layer 12A, the barrier layer 13A, the variable resistance layer 14A, and the second electrode 15A. In an embodiment, the semiconductor device may further include a first conductive line and a second conductive line, such that the memory cell MC is disposed at an intersection between the first and second conductive lines.

The first electrode 11A may be a part of a word line or bit line, or may be electrically connected to the word line or the bit line. The first electrode 11A may include a conductive material such as polysilicon or metal. The first electrode 11A may include polysilicon, tungsten (W), tungsten nitride (WNx), tungsten silicide (WSix), titanium (Ti), titanium nitride (TiNx), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbon nitride (SiCN), copper (Cu), zinc (Zn), nickel (Ni), cobalt (Co), lead (Pd), platinum (Pt), molybdenum (Mo), ruthenium (Ru), or the like, and a combination thereof. For example, the first electrode 11A may include carbon.

The second electrode 15A may be a part of a bit line or word line, or may be electrically connected to the bit line or the word line. When the first electrode 11A is electrically connected to the word line, the second electrode 15A may be electrically connected to the bit line. The second electrode 15A may include a conductive material such as polysilicon or metal. The second electrode 15A may include polysilicon, tungsten (W), tungsten nitride (WNx), tungsten silicide (WSix), titanium (Ti), titanium nitride (TiNx), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbon nitride (SiCN), copper (Cu), zinc (Zn), nickel (Ni), cobalt (Co), lead (Pd), platinum (Pt), molybdenum (Mo), ruthenium (Ru), or the like, and a combination thereof.

The variable resistance layer 14A may be located between the first electrode 11A and the second electrode 15A. The variable resistance layer 14A may include a resistive material and may have a characteristic of reversibly transitioning between different resistance states according to an applied voltage or current.

The variable resistance layer 14A may include transition metal oxide, or metal oxide such as a perovskite-based material. Accordingly, an electrical path is generated or removed in the variable resistance layer 14A, so that data may be stored in a memory cell.

The variable resistance layer 14A may have an MTJ structure, and may include a magnetization-fixed layer, a magnetization free layer, and a tunnel barrier layer interposed therebetween. For example, the magnetization-fixed layer and the magnetization-free layer may each include a magnetic material, and the tunnel barrier layer may include oxide of magnesium (Mg), aluminum (Al), zinc (Zn), titanium (Ti), or the like. The magnetization direction of the magnetization free layer may be changed by spin torque of electrons in an applied current. Accordingly, data may be stored in the memory cell according to a change in the magnetization direction of the magnetization free layer relative to the magnetization direction of the magnetization-fixed layer.

The variable resistance layer 14A may include a phase change material, and may include chalcogenide. The variable resistance layer 14A may include chalcogenide glass, chalcogenide alloy, or the like. The variable resistance layer 14A may include silicon (Si), germanium (Ge), antimony (Sb), tellurium (Te), bismuth (Bi), indium (In), tin (Sn), selenium (Se), or the like, or a combination thereof. The variable resistance layer 14A may be Ge—Sb—Te (GST), and may be Ge₂Sb₂Te₅, Ge₂Sb₂Te₇, Ge₁Sb₂Te₄, Ge₁Sb₄Te₇, or the like. The phase of the variable resistance layer 14A may be changed according to a program operation. For example, the variable resistance layer 14A may have a low-resistance crystalline state by a set operation. The variable resistance layer 14A may also have a high-resistance amorphous state by a reset operation. Accordingly, data may be stored in the memory cell by using a resistance difference according to the phase of the variable resistance layer 14A.

The variable resistance layer 14A may include a variable resistance material whose resistance changes without phase change, and may include a chalcogenide-based material. The variable resistance layer 14A may include germanium (Ge), antimony (Sb), tellurium (Te), arsenic (As), selenium (Se), silicon (Si), indium (In), tin (Sn), sulfur (S), gallium (Ga), or the like, or a combination thereof. The variable resistance layer 14A may include chalcogenide that maintains an amorphous state during a program operation. The variable resistance layer 14A may have an amorphous state and might not be changed to a crystalline state during a program operation. Accordingly, a threshold voltage of the memory cell may be changed according to a program voltage applied to the memory cell, and the memory cell may be programmed into at least two states. For example, when a negative program voltage is applied to the memory cell, the memory cell may have a relatively high threshold voltage. When a positive program voltage is applied to the memory cell, the memory cell may have a relatively low threshold voltage. Accordingly, data may be stored in the memory cell by using a difference between the threshold voltages of the memory cell.

The barrier layer 13A is for changing band gap characteristics of the memory cell MC and may be located between the first electrode 11A and the variable resistance layer 14A. The barrier layer 13A may be located on the anti-oxidation layer 12A. The barrier layer 13A may include a dielectric material such as oxide or nitride. By changing band gap characteristics of the variable resistance layer 14A by the barrier layer 13A including a dielectric material, a difference between the threshold voltages of the memory cell MC according to a program state may be increased, which may increase a read window margin of the memory cell MC and improve characteristics of the memory cell MC.

In order to maintain electrical conductivity of the memory cell MC, the barrier layer 13A may be formed with a thin thickness. When the barrier layer 13A is too thin, a change in the band gap characteristics may not be sufficient, and when the barrier layer 13A is too thick, electrons may not be substantially tunneled and the electrical conductivity of the memory cell may be excessively reduced. Accordingly, the thickness of the barrier layer 13A may be 0.1 nm to 2 nm to enable direct tunneling of electrons. For example, the thickness of the barrier layer 13A may be about 1 nm.

The anti-oxidation layer 12A may be located between the first electrode 11A and the barrier layer 13A. The anti-oxidation layer 12A may be located on the first electrode 11A. The anti-oxidation layer 12A may include a dielectric material such as oxide or nitride. The anti-oxidation layer 12A and the barrier layer 13A may have different dielectric constants. The dielectric constants of the anti-oxidation layer 12A and the barrier layer 13A may each be not greater than 10. In an embodiment, a ratio of the dielectric constant of the anti-oxidation layer 12A to that of the barrier layer 13A may be in a range from 1.4 to 2.4, 1.7 to 2.2, or 1.8 to 2.0. For example, the dielectric constant of the anti-oxidation layer 12A may be about 7.5, and the dielectric constant of the barrier layer 13A may be about 3.9.

When the anti-oxidation layer 12A including a dielectric material is located between the first electrode 11A and the barrier layer 13A, the band gap characteristics of the variable resistance layer 14A may be further changed. By placing dielectric layers having different dielectric constants in a multilayer structure between the first electrode 11A and the variable resistance layer 14A, holes may be accumulated at an interface between the variable resistance layer 14A and the barrier layer 13A and a tunneling difference may be increased by the addition of the anti-oxidation layer 12A, which may further increase the read window margin.

In order to maintain the electrical conductivity of the memory cell MC, the anti-oxidation layer 12A may have a thin thickness. In an embodiment, the anti-oxidation layer 12A may have a thickness sufficient to protect the first electrode 11A from being oxidized or damaged when the barrier layer 13A is formed using a deposition process (e.g., a CVD process). The thickness of the anti-oxidation layer 12A may be 0.1 nm to 2 nm. When the thickness of the anti-oxidation layer 12A is less than 0.1 nm, the anti-oxidation layer 12A may not sufficiently protect the first electrode 11A from being oxidized or damaged during a manufacturing process. When the thickness of the anti-oxidation layer 12A is greater than 2 nm, the electrical conductivity of the memory cell may be excessively reduced. For example, the thickness of the anti-oxidation layer 12A may be about 1 nm. The anti-oxidation layer 12A may form a multilayer structure (e.g., a double layer structure) together with the barrier layer 13A, and the thickness of the multilayer structure may be 0.1 nm to 2 nm. The thickness of the double layer or the multilayer may be about 1 nm. The anti-oxidation layer 12A may include a dielectric material such as oxide or nitride. For example, the anti-oxidation layer 12A may include nitride.

The anti-oxidation layer 12A may protect the first electrode 11A of the memory cell MC during a manufacturing process. When the barrier layer 13A is directly placed on the surface of the first electrode 11A, the first electrode 11A may be damaged. For example, when the first electrode 11A includes carbon and the barrier layer 13A includes oxide, the first electrode 11A may be oxidized, or damaged due to vaporization of carbon into carbon dioxide (CO₂) during the manufacturing process. Accordingly, the anti-oxidation layer 12A is placed between the first electrode 11A and the barrier layer 13A to substantially prevent damage to the first electrode 11A. In such a case, the anti-oxidation layer 12A may be formed using a gas that is less likely to oxidize or vaporize the first electrode 11A.

In the embodiment of FIG. 1A, only the single anti-oxidation layer 12A and the single barrier layer 13A sequentially stacked between the first electrode 11A and the variable resistance layer 14A are shown; however, embodiments of the present disclosure are not limited thereto and a plurality of anti-oxidation layers 12A and a plurality of barrier layers 13A may be placed between the first electrode 11A and the variable resistance layer 14A in combination with each other.

Referring to FIG. 1B, the memory cell MC may include a first electrode 11B, a variable resistance layer 14B, an anti-oxidation layer 12B, a barrier layer 13B, and a second electrode 15B.

The anti-oxidation layer 12B or the barrier layer 13B may be located between the variable resistance layer 14B and the second electrode 15B. For example, the barrier layer 13B may be located on the variable resistance layer 14B, and the anti-oxidation layer 12B may be located between the variable resistance layer 14B and the barrier layer 13B. The second electrode 15B may be located on the barrier layer 13B. The anti-oxidation layer 12B and the barrier layer 13B may each include a dielectric material such as oxide or nitride. For example, the anti-oxidation layer 12B may include nitride and the barrier layer 13B may include oxide.

By changing band gap characteristics of the variable resistance layer 14B by the barrier layer 13B including a dielectric material, a difference between the threshold voltages of the memory cell MC according to a program state may be increased, which may increase the read window margin of the memory cell MC and improve the characteristics of the memory cell MC.

In order to maintain the electrical conductivity of the memory cell MC, the anti-oxidation layer 12B or the barrier layer 13B may be formed with a thin thickness. For example, one or both of the anti-oxidation layer 12B and the barrier layer 13B may each have a thickness of 0.1 nm to 2 nm. For example, one or both of the anti-oxidation layer 12B and the barrier layer 13B may each have a thickness of about 1 nm.

Referring to FIG. 1C, the memory cell MC may include a first electrode 11C, a first anti-oxidation layer 12C, a first barrier layer 13C, a variable resistance layer 14C, a second anti-oxidation layer 12D, a second barrier layer 13D, and a second electrode 15C.

The first anti-oxidation layer 12C or the first barrier layer 13C may be located between the first electrode 11C and the variable resistance layer 14C. For example, the first barrier layer 13C may be located on the first electrode 11C, and the first anti-oxidation layer 12C may be located between the first electrode 11C and the first barrier layer 13C. The variable resistance layer 14C may be located on the first barrier layer 13C.

The second anti-oxidation layer 12D or the second barrier layer 13D may be located between the variable resistance layer 14C and the second electrode 15C. For example, the second barrier layer 13D may be located on the variable resistance layer 14C, and the second anti-oxidation layer 12D may be located between the variable resistance layer 14C and the second barrier layer 13D. The second electrode 15C may be located on the second barrier layer 13D. The anti-oxidation layers 12C and 12D and the barrier layers 13C and 13D may each include a dielectric material such as oxide or nitride. For example, the anti-oxidation layers 12C and 12D may each include nitride, and the barrier layers 13C and 13D may each include oxide.

By changing band gap characteristics of the variable resistance layer 14C by the barrier layers 13C and 13D each including a dielectric material, a difference between the threshold voltages of the memory cell MC according to a program state may be increased, which may increase the read window margin of the memory cell MC and improve the characteristics of the memory cell MC. Although the memory cell MC according to the embodiment of FIG. 1C includes the second anti-oxidation layer 12D disposed on the variable resistance layer 14C and the second barrier layer 13D disposed on the second anti-oxidation layer 12D, embodiments of the present disclosure are not limited thereto. In another embodiment, the memory cell MC may include the second barrier layer 13D disposed on the variable resistance layer 14C and the second anti-oxidation layer 12D disposed on the second barrier layer 13D.

In order to maintain the electrical conductivity of the memory cell MC, one or more of the anti-oxidation layers 12C and 12D and the barrier layers 13C and 13D may each be formed with a thin thickness. For example, one or more of the anti-oxidation layers 12C and 12D and the barrier layers 13C and 13D may each have a thickness of 0.1 nm to 2 nm. For example, one or more of the anti-oxidation layers 12C and 12D and the barrier layers 13C and 13D may each have a thickness of about 1 nm.

The first anti-oxidation layer 12C may substantially prevent the first electrode 11C from being damaged when the first barrier layer 13C is directly placed on the surface of the first electrode 11C. For example, when the first electrode 11C includes carbon and the first barrier layer 13C includes oxide, it is possible to prevent oxidation of the first electrode 11C or vaporization of the carbon of the first electrode 11C into carbon dioxide (CO₂) during a manufacturing process. In such a case, the first anti-oxidation layer 12C may be formed using a gas that reduces oxidation or vaporization the first electrode 11C.

Referring to FIG. 1D, the memory cell MC may include a first electrode 11D, a first anti-oxidation layer 12E, a first barrier layer 13E, a first variable resistance layer 14D, a second electrode 15D, a second anti-oxidation layer 12F, a second barrier layer 13F, a second variable resistance layer 14E, and a third electrode 16.

One or both of the first anti-oxidation layer 12E and the first barrier layer 13E may be located between the first electrode 11D and the first variable resistance layer 14D. For example, the first barrier layer 13E may be located on the first electrode 11D, and the first anti-oxidation layer 12E may be located between the first electrode 11D and the first barrier layer 13E. The first variable resistance layer 14D may be located on the first barrier layer 13E, and the second electrode 15D may be located on the first variable resistance layer 14D.

A selection element may be configured to include the first electrode 11D, the first anti-oxidation layer 12E, the first barrier layer 13E, the first variable resistance layer 14D, or the second electrode 15D, or a combination thereof. For example, such a selection element may include the first electrode 11D, the first anti-oxidation layer 12E, the first barrier layer 13E, the first variable resistance layer 14D, and the second electrode 15D. The selection element may be a diode, a PNP diode, a transistor, vertical transistor, a bipolar junction transistor (BJT), a metal insulator transition (MIT) element, a mixed ionic-electronic conduction (MIEC) element, an ovonic threshold switching (OTS) element, or the like. For example, the first variable resistance layer 14D may include a chalcogenide material. The first electrode 11D may be a bottom electrode, and the second electrode 15D may be an intermediate electrode. The first electrode 11D or the second electrode 15D may include metal or metal nitride. One or both of the first electrode 11D and the second electrode 15D may include carbon.

One or more of the second anti-oxidation layer 12F, the second barrier layer 13F, and the second variable resistance layer 14E may be located between the second electrode 15D and the third electrode 16. For example, the second barrier layer 13F may be located on the second electrode 15D, and the second anti-oxidation layer 12F may be located between the second electrode 15D and the second barrier layer 13F. The second variable resistance layer 14E may be located on the second barrier layer 13F, and the third electrode 16 may be located on the second variable resistance layer 14E.

A memory element may be configured to include the second electrode 15D, the second anti-oxidation layer 12F, the second barrier layer 13F, the second variable resistance layer 14E, or a third electrode pattern 16, or a combination thereof. For example, such a memory element may include the second electrode 15D, the second anti-oxidation layer 12F, the second barrier layer 13F, the second variable resistance layer 14E, and a third electrode pattern 16. The memory element and the selection element may share the second electrode 15D. The second variable resistance layer 14E may include a chalcogenide material. The third electrode 16 may be a top electrode. The third electrode 16 may include metal or metal nitride.

The anti-oxidation layers 12E and 12F and the barrier layers 13E and 13F may each include a dielectric material such as oxide or nitride. For example, the anti-oxidation layers 12E and 12F may each include nitride, and the barrier layers 13E and 13F may each include oxide.

By changing band gap characteristics of the variable resistance layers 14D and 14E by the barrier layers 13E and 13F each including a dielectric material, a difference between the threshold voltages of the memory cell MC according to a program state may be increased, which may increase the read window margin of the memory cell MC and improve the characteristics of the memory cell MC.

In order to maintain the electrical conductivity of the memory cell MC, the anti-oxidation layers 12E and 12F or the barrier layers 13E and 13F may each be formed with a thin thickness. For example, one or more of the anti-oxidation layers 12E and 12F and the barrier layers 13E and 13F may each have a thickness of 0.1 nm to 2 nm. For example, one or more of the anti-oxidation layers 12E and 12F and of the barrier layers 13E and 13F may each have a thickness of about 1 nm.

Each of the anti-oxidation layers 12E and 12F may substantially prevent each of the electrodes 11D and 15D from being damaged when the barrier layers 13E and 13F are directly placed on the surfaces of the electrodes 11D and 15D, respectively. For example, when one or both of the first electrode 11D and the second electrode 15D include carbon and one or both of the first barrier layer 13E and the second barrier layer 13F include oxide, it is possible to prevent oxidation of one or both of the first electrode 11D and the second electrode 15D or vaporization of carbon of one or both of the first electrode 11D and the second electrode 15D into carbon dioxide (CO₂) during a manufacturing process. In such a case, the anti-oxidation layers 12E and 12F may be formed using a gas that is less likely to oxidize or vaporize the electrodes 11D and 15D.

FIG. 1E is a band diagram illustrating relative thicknesses and band gap characteristics of the first electrode 11A, the anti-oxidation layer 12A, the barrier layer 13A, the variable resistance layer 14A, and the second electrode 15A constituting the memory cell MC of FIG. 1A. A first direction I may indicate the thickness of each layer, and a second direction II intersecting the first direction I may indicate the size of a band gap.

The anti-oxidation layer 12A and the barrier layer 13A may each have a relatively smaller thickness than the first electrode 11A, the variable resistance layer 14A, or the second electrode 15A in order to ensure direct tunneling of electrons according to a program state. One or both of the anti-oxidation layer 12A and the barrier layer 13A may each have a thickness of 0.1 nm to 2 nm. For example, the thickness of the anti-oxidation layer 12A may be about 1 nm, and the thickness of the barrier layer 13A may be about 1 nm. The thickness of a double layer of the anti-oxidation layer 12A and the barrier layer 13A or a multilayer including these layers may be about 1 nm.

By placing the anti-oxidation layer 12A and the barrier layer 13A each including a dielectric material between the first electrode 11A and the variable resistance layer 14A, the band gap characteristics of the memory cell MC may be changed, and the characteristics of the memory cell MC may be improved by increasing the read window margin of the memory cell MC. For example, a difference between band gap sizes may occur at an interface between the first electrode 11A and the anti-oxidation layer 12A, a difference between band gap sizes may occur at an interface between the anti-oxidation layer 12A and the barrier layer 13A, and a difference between band gap sizes may occur at an interface between the barrier layer 13A and the variable resistance layer 14A. Accordingly, the band gap characteristics of the memory cell MC may be changed. The dielectric constant of the anti-oxidation layer 12A or the barrier layer 13A may be 1 to 10. For example, the anti-oxidation layer 12A may include nitride having a dielectric constant of about 7.9, and the barrier layer 13A may include oxide having a dielectric constant of about 3.5.

According to the structure described above, the first electrodes 11A to 11D, the anti-oxidation layers 12A to 12F, the barrier layers 13A to 13F, the variable resistance layers 14A to 14E, the second electrodes 15A to 15D, or the third electrode 16 may constitute the memory cell MC, or combinations thereof may configure the memory cell MC. For example, the memory cell MC may include a first electrode, a first anti-oxidation layer, a first barrier layer, a first variable resistance layer, and a second electrode. The memory cell MC may further include a second anti-oxidation layer and a second barrier layer. The memory cell MC may further include a second variable resistance layer and a third electrode. The memory cell MC may serve as a memory element and a selection element at the same time. Alternatively, the memory cell MC may separately include a selection element and a memory element.

The barrier layers 13A to 13F may increase the difference in threshold voltage among the variable resistance layers 14A to 14E to increase the read window, thereby improving the characteristics of the memory cell MC. The anti-oxidation layers 12A to 12F may protect the first electrodes 11A to 11D or the second electrode 15D during the manufacturing process. For example, during the manufacturing process, the first anti-oxidation layers 12A, 12C, and 12E may protect the first electrodes 11A, 11C, and 11D, respectively, and the second anti-oxidation layer 12F may protect the second electrode 15D.

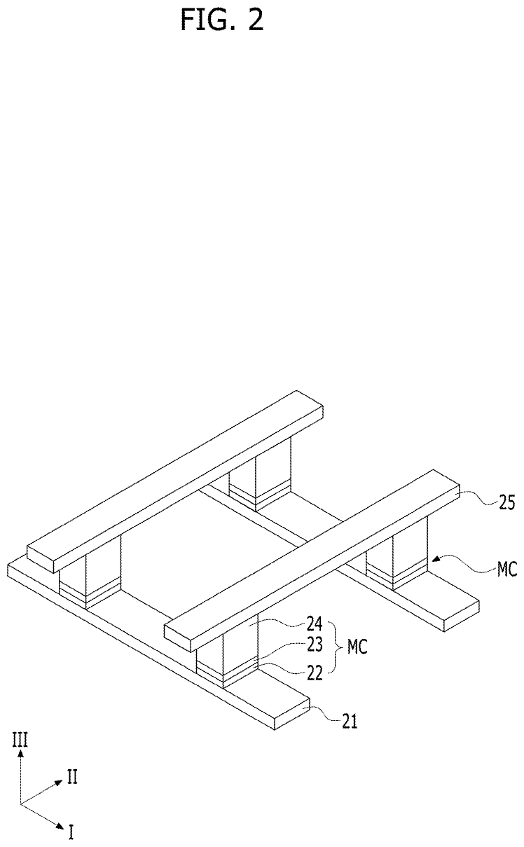

FIG. 2 is a diagram for describing a semiconductor device in accordance with an embodiment. Hereinafter, the content overlapping with the previously described content may be omitted for the interest of brevity.

Referring to FIG. 2, the semiconductor device may include first conductive lines 21, second conductive lines 25, and memory cells MC. The first conductive lines 21 may each extend in a first direction I. The second conductive lines 25 may each extend in a second direction II intersecting the first direction I. The first conductive line 21 may be a word line or a bit line. The second conductive line 25 may be a bit line or a word line. For example, when the first conductive line 21 is a word line, the second conductive line 25 may be a bit line. As another example, when the first conductive line 21 is a bit line, the second conductive line 25 may be a word line.

The memory cells MC may be located at intersection regions of the first conductive lines 21 and the second conductive lines 25. Each of the memory cells MC may include an anti-oxidation layer 22, a barrier layer 23, and a variable resistance layer 24. The anti-oxidation layer 22 may be located between the first conductive line 21 and the barrier layer 23. The barrier layer 23 may be located between the anti-oxidation layer 22 and the variable resistance layer 24. The anti-oxidation layer 22, the barrier layer 23, and the variable resistance layer 24 may be stacked in a third direction III. The third direction III may be a direction protruding from a plane defined by the first direction I and the second direction II, and may protrude vertically from the plane.

Each of the memory cells MC may further include a first electrode located between the first conductive line 21 and the anti-oxidation layer 22 or a second electrode located between the second conductive line 25 and the variable resistance layer 24. Alternatively, a part of the first conductive line 21 may be the first electrode, or a part of the second conductive line 25 may be the second electrode.

Although FIG. 2 illustrates a structure in which the memory cells MC are arranged in the first direction I and the second direction II, the memory cells MC may be stacked in the third direction III. The first conductive lines 21 and the second conductive lines 25 may be alternately stacked, and the memory cells MC may be located between the stacked first conductive lines 21 and second conductive lines 25.

Although not illustrated in this drawing, the anti-oxidation layer 22 and the barrier layer 23 may also be located on the variable resistance layer 24.

The semiconductor device may also include a first anti-oxidation layer 22, a first barrier layer 23, the variable resistance layer 24, a second anti-oxidation layer, or a second barrier layer, or a combination thereof. In such a case, the semiconductor device may also include a structure in which the first anti-oxidation layer 22, the first barrier layer 23, and the variable resistance layer 24 are sequentially stacked and the second anti-oxidation layer and the second barrier layer are sequentially stacked on the variable resistance layer 24. The memory cells MC may have structures including various combinations of the structures of the memory cells MC in FIG. 1A to FIG. 1D.

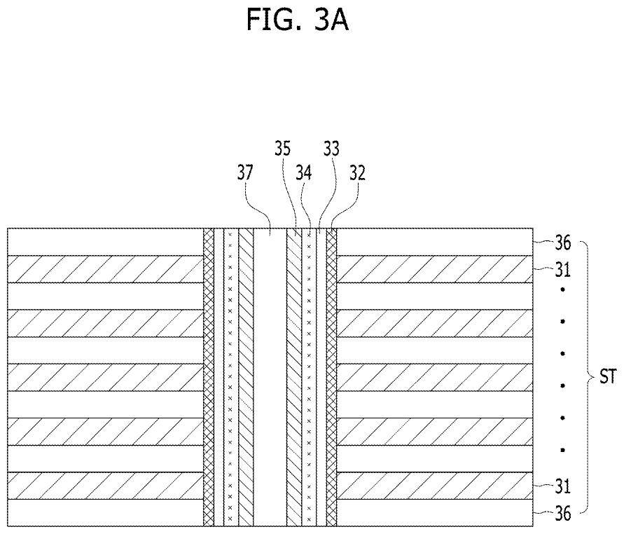

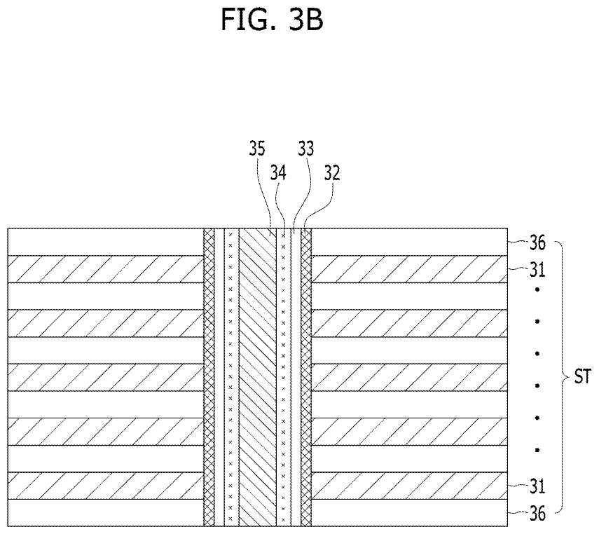

FIG. 3A and FIG. 3B are diagrams for explaining a semiconductor device in accordance with an embodiment. Hereinafter, the content overlapping with the previously described content may be omitted for the interest of brevity.

Referring to FIG. 3A and FIG. 3B, the semiconductor device may include a stack ST, an anti-oxidation layer 32, a barrier layer 33, a variable resistance layer 34, and a second conductive line 35. The semiconductor device may further include a gap fill layer 37.

The stack ST may include first conductive lines 31 and insulating layers 36 that are alternately stacked. The first conductive lines 31 may each include a conductive material such as polysilicon or metal. The first conductive lines 31 may each include polysilicon, tungsten (W), tungsten nitride (WNx), tungsten silicide (WSix), titanium (Ti), titanium nitride (TiNx), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbon nitride (SiCN), copper (Cu), zinc (Zn), nickel (Ni), cobalt (Co), lead (Pd), platinum (Pt), molybdenum (Mo), ruthenium (Ru), or the like, or a combination thereof. For example, the first conductive lines 31 may each include carbon. The first conductive lines 31 may be word lines or bit lines. The insulating layers 36 are for insulating the first conductive lines 31 from each other, and may each include an insulating material such as oxide or nitride.

The second conductive line 35 may pass through the stack ST. Referring to FIG. 3A, the gap fill layer 37 may be located in the second conductive line 35. However, embodiments of the present disclosure are not limited thereto. Referring to FIG. 3B, the semiconductor device may have a structure in which a center area of the semiconductor device is filled with the second conductive line 35. In such a case, the gap fill layer 37 may not be located in the second conductive line 35.

The second conductive line 35 may include polysilicon, tungsten (W), tungsten nitride (WNx), tungsten silicide (WSix), titanium (Ti), titanium nitride (TiNx), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbon nitride (SiCN), copper (Cu), zinc (Zn), nickel (Ni), cobalt (Co), lead (Pd), platinum (Pt), molybdenum (Mo), ruthenium (Ru), or the like, or a combination thereof. The second conductive line 35 may be a bit line or a word line. When the first conductive line 31 is a word line, the second conductive line 35 may be a bit line. Alternatively, a part of the first conductive line 31 may be a first electrode or a part of the second conductive line may be a second electrode.

The variable resistance layer 34 may be located between the first conductive lines 31 and the second conductive line 35. For example, the variable resistance layer 34 may be located to surround a sidewall of the second conductive line 35.

The barrier layer 33 may be located between the variable resistance layer 34 and the first conductive lines 31. The barrier layer 33 may be located to surround a sidewall of the variable resistance layer 34.

The anti-oxidation layer 32 may be located between the barrier layer 33 and the first conductive lines 31. The anti-oxidation layer 32 may be located to surround a sidewall of the barrier layer 33.

Although not illustrated in this drawing, the anti-oxidation layer 32 and the barrier layer 33 may be located between the variable resistance layer 34 and the second conductive line 35. In such a case, the barrier layer 33 may be located to surround the sidewall of the second conductive line 35, and the anti-oxidation layer 32 may be located to surround the sidewall of the barrier layer 33.

The semiconductor device may also include the first conductive lines 31, the variable resistance layer 34, a first anti-oxidation layer 32, a second anti-oxidation layer, a first barrier layer 33, a second barrier layer, or a second conductive line, or a combination thereof. In such a case, one or both of the first anti-oxidation layer 32 and the first barrier layer 33 may be located between the variable resistance layer 34 and the first conductive lines 31, and one or both of the second anti-oxidation layer and the second barrier layer may be located between the variable resistance layer 34 and the second conductive line 35.

According to the structure described above, memory cells may be located at intersection regions of the first conductive lines 31 and the second conductive line 35. The stacked memory cells may share the anti-oxidation layer 32, the barrier layer 33, the variable resistance layer 34, and the second conductive line 35.

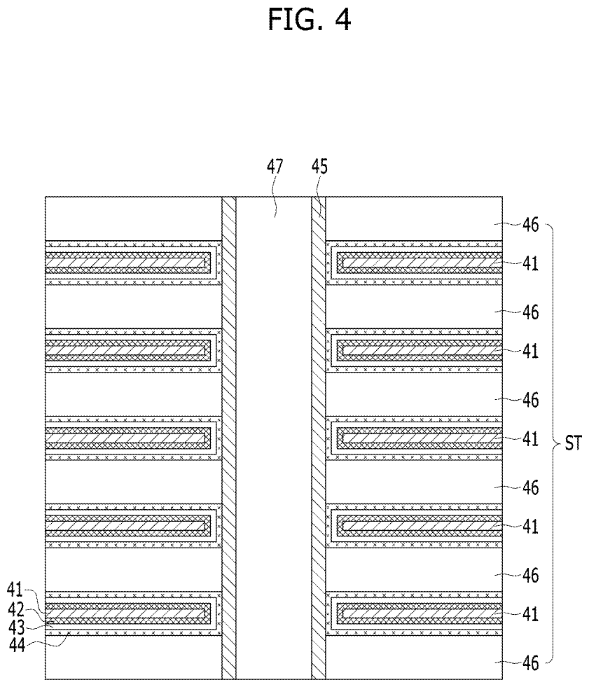

FIG. 4 is a diagram for describing the structure of a semiconductor device in accordance with an embodiment. Hereinafter, the content overlapping with the previously described content may be omitted for the interest of brevity.

Referring to FIG. 4, the semiconductor device may include a stack ST, an anti-oxidation layer 42, a barrier layer 43, a variable resistance layer 44, and a second conductive line 45. The semiconductor device may further include a gap fill layer 47.

The stack ST may include first conductive lines 41 and insulating layers 46 that are alternately stacked. The gap fill layer 47 may be located in the second conductive line 45. However, embodiments of the present disclosure are not limited thereto, and the semiconductor device may have a structure in which a center area of the semiconductor device is filled with the second conductive line 45. In such a case, the gap fill layer 47 may not be located in the second conductive line 45. A part of the first conductive line 41 may be a first electrode, or a part of the second conductive line 45 may be a second electrode.

Each of the barrier layers 43 may be located between the first conductive lines 41 and the second conductive line 45, and may extend between the insulating layers 46 and the first conductive lines 41. The barrier layers 43 may surround the anti-oxidation layers 42, respectively. Each of the barrier layers 43 may have a C-shaped cross section.

Each of the anti-oxidation layers 42 may be located between the first conductive lines 41 and the second conductive line 45, and may extend between the insulating layers 46 and the first conductive lines 41. Each of the anti-oxidation layers 42 may be located between the barrier layers 43 and the first conductive lines 41. Each of the anti-oxidation layers 32 may have a C-shaped cross section.

Each of the variable resistance layers 44 may be located between the first conductive lines 41 and the second conductive line 45, and may extend between the insulating layers 46 and the first conductive lines 41. The variable resistance layers 44 may surround the barrier layers 43, respectively. Each of the variable resistance layers 44 may have a C-shaped cross section.

Although not illustrated in this drawing, the anti-oxidation layer 42 and the barrier layer 43 may be located between the variable resistance layer 44 and the second conductive line 45. In such a case, the anti-oxidation layer 42 may be located to surround a sidewall of the variable resistance layer 44, and the barrier layer 43 may be located to surround a sidewall of the anti-oxidation layer 42.

The semiconductor device may also include the first conductive lines 41, the second conductive line 45, the variable resistance layer 44, a first anti-oxidation layer 42, a second anti-oxidation layer, a first barrier layer 43, and a second barrier layer, or a combination thereof. In such a case, one or both of the first anti-oxidation layer 42 and the first barrier layer 43 may be located between the variable resistance layer 44 and the first conductive lines 41, and one or both of the second anti-oxidation layer and the second barrier layer may be located between the variable resistance layer 44 and the second conductive line 45.

According to the structure described above, memory cells may be located at intersection regions of the first conductive lines 41 and the second conductive line 45. The anti-oxidation layers 42, the barrier layers 43, and the variable resistance layers 44 of the stacked memory cells may be separated from each other. The stacked memory cells may share the second conductive line 45.

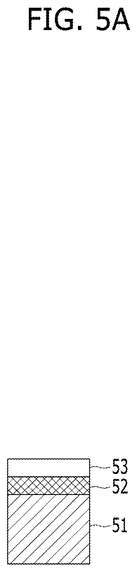

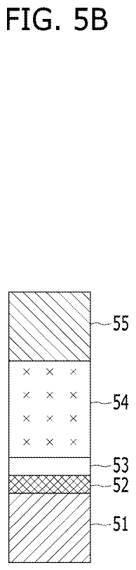

FIG. 5A and FIG. 5B are diagrams for describing a method of manufacturing a semiconductor device in accordance with an embodiment. Hereinafter, the content overlapping with the previously described content may be omitted for the interest of brevity.

Referring to FIG. 5A and FIG. 5B, a first electrode 51 may be formed. The first electrode 51 may include carbon. Next, an anti-oxidation layer 52 may be formed on the first electrode 51. The anti-oxidation layer 52 may include a dielectric material such as oxide or nitride. For example, the anti-oxidation layer 52 may include nitride. The anti-oxidation layer 52 may be formed by a deposition method. For example, the anti-oxidation layer 52 may be deposited using a chemical vapor deposition (CVD) method.

Subsequently, a barrier layer 53 may be formed on the anti-oxidation layer 52. The barrier layer 53 may include a dielectric material such as oxide or nitride. For example, the barrier layer 53 may be oxide. The barrier layer 53 may be formed on the anti-oxidation layer 52 by a CVD method.

Subsequently, a variable resistance layer 54 may be formed. The variable resistance layer 54 may include chalcogenide. Subsequently, a second electrode 55 may be formed on the variable resistance layer 54.

When an oxide layer is directly formed on a surface of the first electrode 51, the first electrode 51 may be damaged. For example, when the first electrode 51 includes carbon, the carbon of the first electrode 51 may be vaporized into carbon dioxide (CO₂) due to a gas for depositing the oxide layer. Accordingly, the anti-oxidation layer 52 is formed on the surface of the first electrode 51 before the oxide layer is deposited, which may substantially prevent damage to the first electrode 51.

The anti-oxidation layer 52 may be formed using a deposition gas that minimizes damage to the first electrode 51. Accordingly, the anti-oxidation layer 52 may be formed while damage to the first electrode 51 is minimized.

The barrier layer 53 may be formed while the anti-oxidation layer 52 protects the first electrode 51. For example, when the first electrode 51 includes carbon and the barrier layer 53 includes oxide, the barrier layer 53 may be deposited without damage to the first electrode 51 because the anti-oxidation layer 52 protects the first electrode 51 during a process of depositing the barrier layer 53.

By forming the barrier layer 53 including a dielectric material between the first electrode 51 and the variable resistance layer 54, bandgap characteristics of the variable resistance layer 54 may be changed, resulting in an increase in a difference between the threshold voltages of the memory cell MC according to a program state, which may increase the read window margin of the memory cell MC and improve the characteristics of the memory cell MC.

In order to maintain the electrical conductivity of the memory cell MC, the anti-oxidation layer 52 or the barrier layer 53 may be formed with a thin thickness. When one or both of the anti-oxidation layer 52 and the barrier layer 53 are too thin, a change in bandgap characteristics may not be sufficient, and when one or both of the anti-oxidation layer 52 and the barrier layer 53 are too thick, electrons may not be substantially tunneled and the electrical conductivity of the memory cell may be excessively reduced. Accordingly, one or both of the anti-oxidation layer 52 and the barrier layer 53 may each have a thickness of 0.1 nm to 2 nm to enable direct tunneling of electrons. For example, one or both of the anti-oxidation layer 52 and the barrier layer 53 may have a thickness of about 1 nm.

When the anti-oxidation layer 52 and the barrier layer 53 each including a dielectric material are formed between the first electrode 51 and the variable resistance layer 54, the bandgap characteristics of the variable resistance layer 54 may be further changed. By placing dielectric layers having different dielectric constants in a multilayer structure between the first electrode 51 and the variable resistance layer 54, holes may be accumulated at an interface between the variable resistance layer 54 and the barrier layer 53 and a difference in electron tunneling may be increased, which may further increase the read window margin. For example, the dielectric constant of the anti-oxidation layer 52 may be about 7.5, and the dielectric constant of the barrier layer 53 may be about 3.9.

Although not illustrated in this drawing, a first conductive line may be formed before the first electrode 51 is formed. After the second electrode 55 is formed, a second conductive line connected to the second electrode 55 may be formed. The second conductive line may be formed in a direction intersecting the first conductive line.

According to the process described above, when the anti-oxidation layer 52 and the barrier layer 53 are formed between the first electrode 51 and the variable resistance layer 54, the first electrode 51 may be protected and the characteristics of the memory cell may be improved.

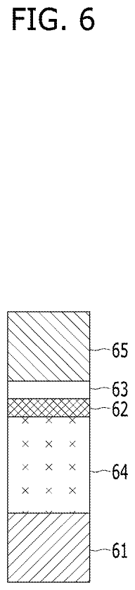

FIG. 6 is a diagram for describing a method of manufacturing a semiconductor device in accordance with an embodiment. Hereinafter, the content overlapping with the previously described content may be omitted for the interest of brevity.

Referring to FIG. 6, a variable resistance layer 64 may be formed on the first electrode 61. Subsequently, an anti-oxidation layer 62 may be formed on the variable resistance layer 64. The anti-oxidation layer 62 may be deposited by a CVD method. The anti-oxidation layer 62 may include a dielectric material such as oxide or nitride. For example, the anti-oxidation layer 62 may include nitride.

Subsequently, a barrier layer 63 may be formed on the anti-oxidation layer 62. The barrier layer 63 may be deposited by a CVD method. The barrier layer 63 may include a dielectric material such as oxide or nitride. For example, the barrier layer 63 may include oxide. Subsequently, a second electrode 65 may be formed on the barrier layer 63.

According to the process described above, by forming the barrier layer 63 including a dielectric material on the variable resistance layer 64, the read margin of the memory cell MC may be increased and the characteristics of the memory cell MC may be improved.

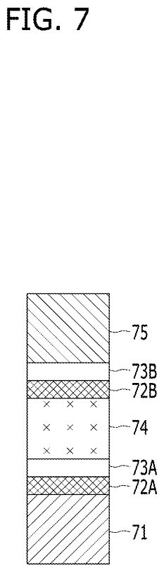

FIG. 7 is a diagram for describing a method of manufacturing a semiconductor device in accordance with an embodiment. Hereinafter, the content overlapping with the previously described content may be omitted for the interest of brevity.

Referring to FIG. 7, a first anti-oxidation layer 72A may be formed on a first electrode 71. The first anti-oxidation layer 72A may be deposited by a CVD method. Subsequently, a first barrier layer 73A may be formed on the first anti-oxidation layer 72A. The first barrier layer 73A may be deposited by a CVD method. The first anti-oxidation layer 72A and the first barrier layer 73A may each include a dielectric material such as oxide or nitride. For example, the first anti-oxidation layer 72A may include nitride and the first barrier layer 73A may include oxide.

The first anti-oxidation layer 72A may substantially prevent the first electrode 71 from being oxidized or vaporized when the first barrier layer 73A is formed on the first electrode 71. For example, when the first electrode 71 includes carbon, the first anti-oxidation layer 72A including nitride is formed to substantially prevent the carbon of the first electrode 71 from being vaporized into carbon dioxide (CO₂) when the first barrier layer 73A including oxide is formed.

Subsequently, a variable resistance layer 74 may be formed on the first barrier layer 73A. Subsequently, a second anti-oxidation layer 72B and a second barrier layer 73B may be sequentially formed on the variable resistance layer 74. The second anti-oxidation layer 72B and the second barrier layer 73B may be deposited by a CVD method and may each include a dielectric material such as oxide or nitride. Subsequently, a second electrode 75 may be formed on the second barrier layer 73B.

By placing the barrier layers 73A and 73B each including a dielectric material above or below the variable resistance layer 74, the read window of the memory cell MC may be increased and the characteristics of the memory cell MC may be improved.

Although embodiments according to the technical idea of the present disclosure have been described above with reference to the accompanying drawings, this is only for explaining the embodiments according to the concept of the present disclosure, and embodiments of the present disclosure are not limited to the above embodiments. Various types of substitutions, modifications, and changes for the embodiments may be made by those skilled in the art, to which the present disclosure pertains, without departing from the technical idea of the present disclosure defined in the following claims, and these substitutions, modifications, and changes may belong to the scope of the present disclosure.

What is claimed is:

1. A semiconductor device comprising:
a first electrode including carbon;
an anti-oxidation layer located on the first electrode;
a barrier layer located on the anti-oxidation layer and including oxide;
a variable resistance layer located on the barrier layer; and
a second electrode located on the variable resistance layer.

2. The semiconductor device of claim 1, wherein the anti-oxidation layer includes nitride.

3. The semiconductor device of claim 1, wherein the variable resistance layer maintains an amorphous state during a program operation.

4. The semiconductor device of claim 1, wherein the variable resistance layer includes chalcogenide.

5. The semiconductor device of claim 1, further comprising:
a first conductive line extending in a first direction and connected to the first electrode; and
a second conductive line extending in a second direction intersecting the first direction and connected to the second electrode.

6. The semiconductor device of claim 1, wherein one or both of the anti-oxidation layer and the barrier layer each have a thickness of 0.1 nm to 2 nm.

7. The semiconductor device of claim 1, wherein a multilayer structure including the anti-oxidation layer and the barrier layer has a thickness of 0.1 nm to 2 nm.

8. The semiconductor device of claim 1, wherein the anti-oxidation layer is a first anti-oxidation layer and the barrier layer is a first barrier layer, the device further comprising:
a second anti-oxidation layer located on the variable resistance layer; and
a second barrier layer located between the second anti-oxidation layer and the second electrode.

9. The semiconductor device of claim 1, wherein the anti-oxidation layer is a first anti-oxidation layer, the barrier layer is a first barrier layer and the variable resistance layer is a first resistance layer the device further comprising:
a second anti-oxidation layer located on the second electrode;
a second barrier layer located on the second anti-oxidation layer;
a second variable resistance layer located on the second barrier layer; and
a third electrode located on the second variable resistance layer.

10. The semiconductor device of claim 1, wherein a ratio of a dielectric constant of the anti-oxidation layer to that of the barrier layer is in a range from 1.4 to 2.4.

11. A method of manufacturing a semiconductor device, the method comprising:
forming a first electrode including carbon;
forming an anti-oxidation layer on the first electrode;
forming a barrier layer including oxide on the anti-oxidation layer;
forming a variable resistance layer on the barrier layer; and
forming a second electrode on the variable resistance layer.

12. The method of claim 11, wherein the anti-oxidation layer includes nitride.

13. The method of claim 11, wherein the variable resistance layer maintains an amorphous state during a program operation.

14. The method of claim 11, wherein the variable resistance layer includes chalcogenide.

15. The method of claim 11, wherein one or both of the anti-oxidation layer and the barrier layer each have a thickness of 0.1 nm to 2 nm.

16. The method of claim 11, wherein a multilayer structure including the anti-oxidation layer and the barrier layer has a thickness of 0.1 nm to 2 nm.

17. The method of claim 11, wherein the barrier layer is formed using a CVD process, and
wherein the anti-oxidation layer includes nitride having a thickness sufficient to protect the first electrode from being oxidized or damaged when the barrier layer is formed using the CVD process.

18. The method of claim 11, wherein the anti-oxidation layer is a first anti-oxidation layer and the barrier layer is a first barrier layer, the method further comprising:
forming a second anti-oxidation layer and a second barrier layer on the variable resistance layer.
